(19) United States
(12) Patent Application Publication
(10) Pub. No.: US 2024/0292572 A1
(43) Pub. Date: Aug. 29, 2024

(54) DISPLAY DEVICE

(71) Applicant: LG Display Co., Ltd., Seoul (KR)

(72) Inventors: Eunjeong YANG, Goyang-si (KR); Daehyun SEO, Jeonju-si (KR)

(21) Appl. No.: 18/442,638

(22) Filed: Feb. 15, 2024

(30) Foreign Application Priority Data
Feb. 28, 2023 (KR) 10-2023-0026967

(51) Int. Cl. H05K 7/20; H01L 23/367; H01L 25/16; H05K 1/18

(52) U.S. Cl. CPC H05K 7/20509; H01L 23/367; H01L 25/167; H05K 1/18; H05K 2201/10128

(57) ABSTRACT

Provided is a display device. According to an aspect of the present disclosure, there is provided a display device. The display device comprises a display panel, a cover bottom which is disposed on a rear surface of the display panel and includes a first opening. The display device further comprises a plate bottom which is disposed to overlap the first opening on the rear surface of the display panel. The display device further comprises a printed circuit board which is disposed on a rear surface of the plate bottom and is connected to the display panel. The display device further comprises a heat dissipation sheet disposed between the display panel and the printed circuit board. Therefore, heat generated from a printed circuit board can be uniformly diffused to the entire display panel, and the entire temperature deviation of the display panel can be reduced.

### CROSS-REFERENCE TO RELATED APPLICATIONS

This application claims the priority of Korean Patent Application No. 10-2023-0026967 filed on Feb. 28, 2023, in the Korean Intellectual Property Office, the disclosure of which is incorporated herein by reference.

### BACKGROUND

### Technical Field

The present disclosure relates to a display device, and more particularly, to a display device using a light emitting diode (LED).

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### BRIEF SUMMARY

Various embodiments of the present disclosure provide a display device which uniformly implements the overall temperature of a display panel.

Various embodiments of the present disclosure provide a display device which improves a display quality by reducing a temperature deviation of a display panel.

Various embodiments of the present disclosure provide a display device which uniformly diffuses heat generated from a printed circuit board to the entire display panel.

Various embodiments of the present disclosure provide a display device which reduces or minimizes spots or color differences by reducing a temperature difference between an area in which a printed circuit board is disposed and an area in which the printed circuit board is not disposed.

Technical benefits of the present disclosure are not limited to the above-mentioned benefits, and other benefits, which are not mentioned above, can be clearly understood by those skilled in the art from the following descriptions.

According to an aspect of the present disclosure, there is provided a display device. The display device comprises a display panel, a cover bottom which is disposed on a rear surface of the display panel and includes a first opening. The display device further comprises a plate bottom which is disposed to overlap the first opening on the rear surface of the display panel. The display device further comprises a printed circuit board which is disposed on a rear surface of the plate bottom and is connected to the display panel. The display device further comprises a heat dissipation sheet disposed between the display panel and the printed circuit board. Therefore, heat generated from a printed circuit board can be uniformly diffused to the entire display panel, and the entire temperature deviation of the display panel can be reduced.

Other detailed matters of the exemplary embodiments are included in the detailed description and the drawings.

According to the present disclosure, a temperature deviation in the entire area of the display panel is reduced or minimized.

According to the present disclosure, heat generated from the printed circuit board is diffused to the entire display panel so that the concentration of the heat on a partial area of the display panel is reduced or minimized.

According to the present disclosure, spots, or color differences due to the temperature deviation in the display panel are reduced or minimized to improve a display quality.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is a plan view of a display panel of a display device according to an exemplary embodiment of the present disclosure;

FIG. 4 is a cross-sectional view of a display device according to an exemplary embodiment of the present disclosure;

FIG. 5 is an exploded perspective view of a display device according to an exemplary embodiment of the present disclosure;

FIG. 6 is a rear view of a display device according to an exemplary embodiment of the present disclosure;

FIG. 7 is a cross-sectional view taken along the line VII-VII′ of FIG. 6;

FIG. 8 is a cross-sectional view of a display device according to another exemplary embodiment of the present disclosure;

FIG. 9 is a cross-sectional view of a display device according to still another exemplary embodiment of the present disclosure; and

FIG. 10 is a cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

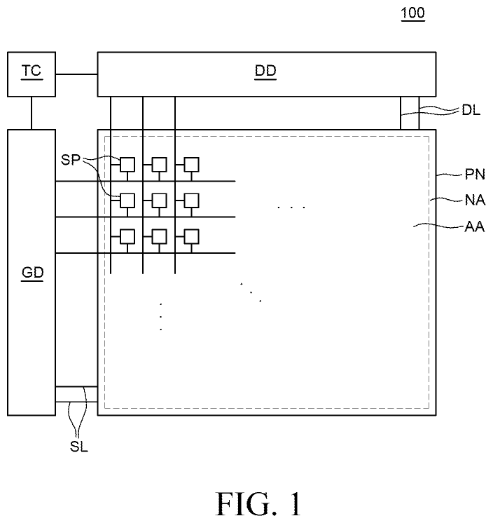

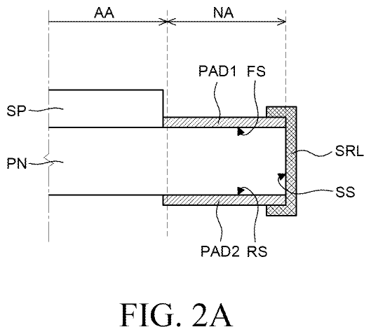

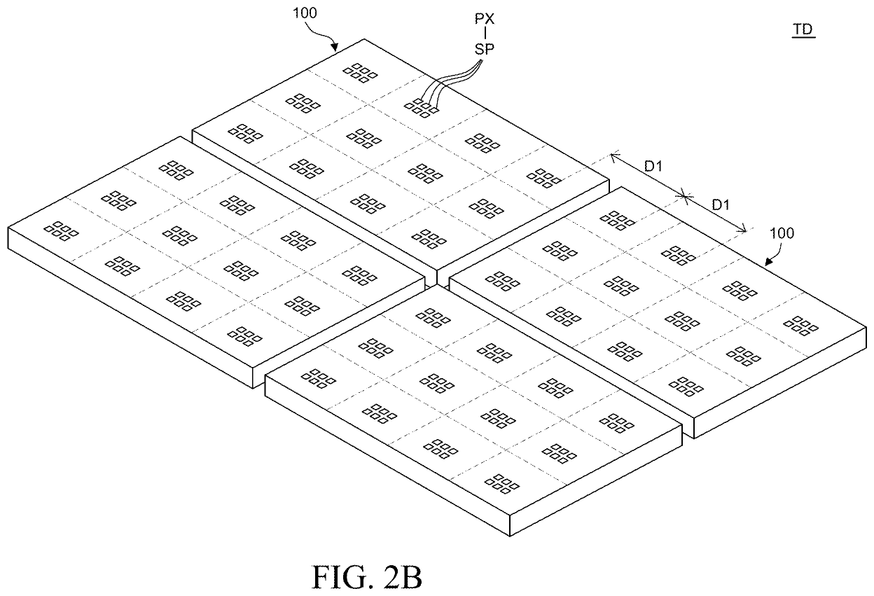

FIG. 1 is a schematic diagram of a display device according to an exemplary embodiment of the present disclosure. FIG. 2A is a partial cross-sectional view of a display device according to an exemplary embodiment of the present disclosure. FIG. 2B is a perspective view of a tiling display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL in accordance with a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and the non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP may form one pixel PX. In each of the plurality of sub pixels SP, a light emitting diode, a thin film transistor for driving the light emitting diode, and the like may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

In the active area AA, a plurality of wiring lines which transmits various signals to the plurality of sub pixels SP is disposed. For example, the plurality of wiring lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL extends in one direction in the active area AA to be connected to the plurality of sub pixels SP and the plurality of data lines DL extends in a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, a driving IC, such as a gate driver IC or a data driver IC, or the like may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board. The data driver DD and the timing controller TC may be electrically connected to the display panel PN by bonding the flexible film and the printed circuit board to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be reduced or minimized on the front surface of the display panel PN. That is, when the gate driver GD, the data driver DD, and the timing controller TC are connected to the display panel PN as described above, a zero bezel with substantially no bezel may be implemented.

Specifically, referring to FIGS. 2A and 2B, in the non-active area NA of the display panel PN, a plurality of pad electrodes for transmitting various signals to the plurality of sub pixels SP is disposed. For example, in the non-active area NA on the front surface FS of the display panel PN, a first pad electrode PAD1 which transmits a signal to the plurality of sub pixels SP is disposed. In the non-active area NA on the rear surface RS of the display panel PN, a second pad electrode PAD2 which is electrically connected to a driving component, such as a flexible film and the printed circuit board, is disposed. That is, on the front surface FS of the display panel PN on which images are displayed, only a pad area of the non-active area NA in which the first pad electrode PAD1 is disposed may be formed at minimum.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface SS of the display panel PN. The side line SRL may electrically connect a first pad electrode PAD1 on the front surface FS of the display panel PN and a second pad electrode PAD2 on the rear surface RS of the display panel PN. Therefore, a signal from a driving component on the rear surface RS of the display panel PN may be transmitted to the plurality of sub pixels SP through the second pad electrode PAD2, the side line SRL, and the first pad electrode PAD1. Accordingly, a signal transmitting path from the front surface FS of the display panel PN to the side surface SS and the rear surface RS is formed to reduce or minimize an area of the non-active area NA on the front surface FS of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a reduced or minimized bezel, a seam area in which an image between the display devices 100 is not displayed is reduced or minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, a constant distance D1 between pixels PX between the display devices 100 is configured to reduce or minimize the seam area.

However, FIGS. 2A and 2B are illustrative so that the display device 100 according to the exemplary embodiment of the present disclosure may be a general display device 100 with a bezel, but is not limited thereto.

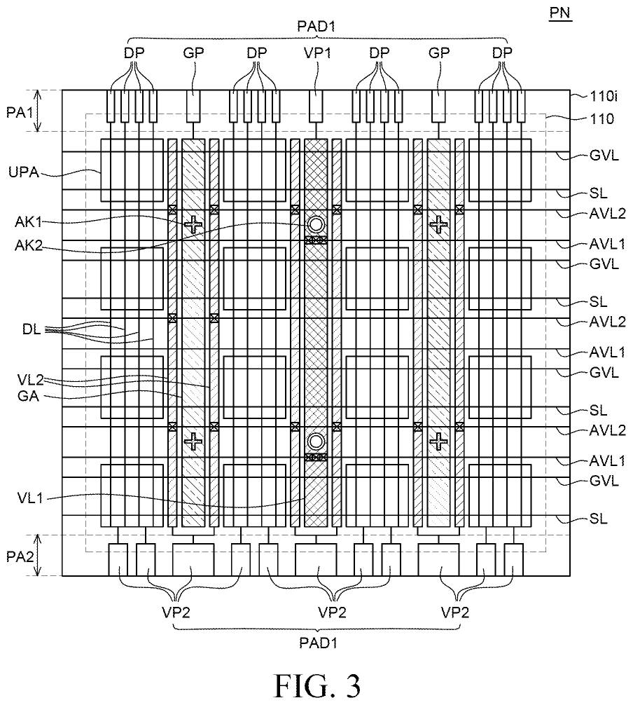

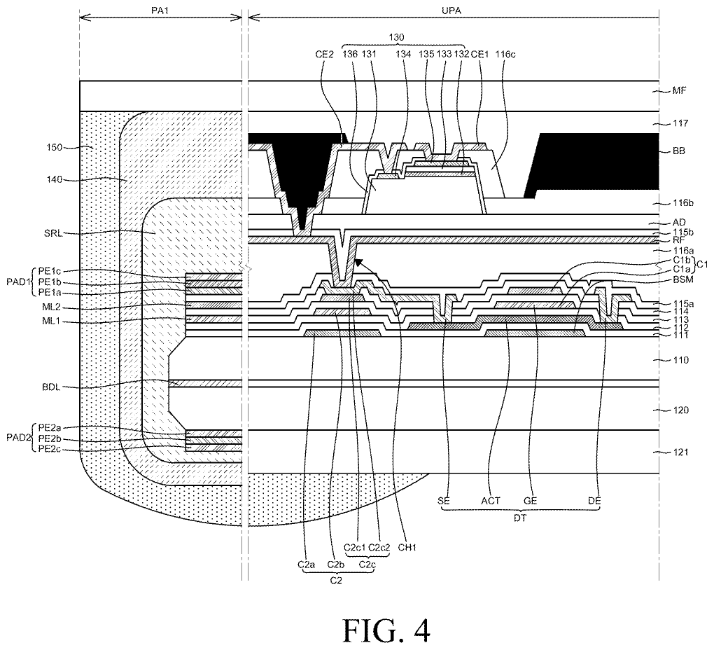

FIG. 3 is a plan view of a display panel of a display device according to an exemplary embodiment of the present disclosure. FIG. 4 is a cross-sectional view of a display device according to an exemplary embodiment of the present disclosure.

First, referring to FIGS. 3 and 4, the display panel PN includes a first substrate 110. The first substrate 110 is a substrate which supports components disposed above the display device 100 and may be an insulating substrate. A plurality of pixels PX is formed on the first substrate 110 to display images. For example, the first substrate 110 may be formed of glass or resin. Further, the first substrate 110 may include polymer or plastic. In some exemplary embodiments, the first substrate 110 may be formed of a plastic material having flexibility.

In the first substrate 110, a plurality of pixel areas UPA, a plurality of gate driving areas GA, and a plurality of pad areas PA1 and PA2 are disposed. Among them, the plurality of pixel areas UPA and the plurality of gate driving areas GA may be included in the active area AA of the display panel PN.

First, the plurality of pixel areas UPA is areas in which the plurality of pixels PX is disposed. The plurality of pixel areas UPA may be disposed by forming a plurality of rows and a plurality of columns. Each of the plurality of pixels PX disposed in the plurality of pixel areas UPA includes a plurality of sub pixels SP. Each of the plurality of sub pixels SP includes a light emitting diode 130 and a pixel circuit to independently emit light. The plurality of sub pixels SP may include a plurality of sub pixels SP which emits different color light. For example, the plurality of sub pixels SP may include a red sub pixel, a blue sub pixel, a green sub pixel, and the like, but is not limited thereto.

The plurality of gate driving areas GA is areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. At this time, the gate driver may include, for example, a plurality of transistors and/or capacitors. Here, active layers of the plurality of transistors may be formed of a semiconductor material, such as an oxide semiconductor, amorphous silicon, or polysilicon, but are not limited thereto. At this time, the active layers of the plurality of transistors may be formed of the same material or different materials from each other. Further, the active layers of the transistors of the gate driver may be formed of the same material as active layers of various transistors of the pixel circuit or formed of different materials from each other.

The plurality of pad areas PA1 and PA2 is areas in which a plurality of first pad electrodes PAD1 is disposed. The plurality of first pad electrodes PAD1 may transmit various signals to various wiring lines extending in a column direction in the active area AA. For example, the plurality of first pad electrodes PAD1 includes a data pad DP, a gate pad GP, a high potential power pad VP1, and a low potential power pad VP2. The data pad DP transmits a data voltage to the data line DL and the gate pad GP transmits a clock signal, a start signal, a gate low voltage, and a gate high voltage for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas PA1 and PA2 includes a first pad area PA1 located at an upper edge of the display panel PN and a second pad area PA2 of the display panel PN. At this time, in the first pad area PA1 and the second pad area PA2, different types of first pad electrodes PAD1 may be disposed. For example, in the first pad area PA1, among the plurality of first pad electrodes PAD1, the data pad DP, the gate pad GP, and the high potential power pad VP1 are disposed and in the second pad area PA2, the low potential power pad VP2 may be disposed.

At this time, the plurality of first pad electrodes PAD1 may be formed to have different sizes, respectively. For example, the plurality of data pads DP which is connected to the plurality of data lines DL one to one may have a narrower width and the high potential power pad VP1, the low potential power pad VP2, and the gate pad GP may have a larger width. However, widths of the data pad DP, the gate pad GP, the high potential power pad VP1, and the low potential power pad VP2 illustrated in FIG. 3 are illustrative so that the first pad electrode PAD1 may be configured in various sizes, but is not limited thereto.

In the meantime, in order to reduce the bezel of the display panel PN, an edge of the display panel PN may be cut to be removed. The plurality of pixels PX, the plurality of wiring lines, and the plurality of first pad electrodes PAD1 are formed on an initial first substrate 110i and an edge part of the initial first substrate 110i is ground to reduce the bezel area. During the grinding process, a part of the initial first substrate 110i is removed to form a first substrate 110 with a smaller size. At this time, parts of the plurality of first pad electrodes PAD1 and wiring lines disposed at the edge of the first substrate 110 may be removed. Accordingly, only a part of the plurality of first pad electrodes PAD1 may remain on the first substrate 110.

Next, the plurality of data lines DL which extends in a column direction from the plurality of first pad electrodes PAD1 is disposed on the first substrate 110 of the display panel PN. The plurality of data lines DL may extend from the plurality of data pads DP of the first pad area PA1 toward the plurality of pixel areas UPA. The plurality of data lines DL may extend in a column direction and overlap the plurality of pixel areas UPA. Therefore, the plurality of data lines DL may transmit the data voltage to the pixel circuit of each of the plurality of sub pixels SP.

The plurality of high potential power lines VL1 extending in the column direction is disposed on the first substrate 110 of the display panel PN. Some of the plurality of high potential power lines VL1 extend from the high potential power pad VP1 of the first pad area PA1 to the plurality of pixel areas UPA to transmit the high potential power voltage to the light emitting diode 130 of each of the plurality of sub pixels SP. The others of the plurality of high potential power lines VL1 may be electrically connected to the other high potential power line VL1 by means of an auxiliary high potential power line AVL1 to be described below. In FIG. 3, for the convenience of description, even though it is illustrated that one high potential power line VL1 and one high potential power pad VP1 are disposed, a plurality of high potential power lines VL1 and high potential power pads VP1 may be disposed.

The plurality of low potential power lines VL2 extending in the column direction is disposed on the first substrate 110 of the display panel PN. At least some of the plurality of low potential power lines VL2 extend from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 may be electrically connected to the other low potential power line VL2 by means of an auxiliary low potential power line AVL2 to be described below.

The plurality of scan lines SL extending in the row direction is disposed on the first substrate 110 of the display panel PN. The plurality of scan lines SL extends in the row direction and may be disposed across the plurality of pixel areas UPA and the plurality of gate driving areas GA. The plurality of scan lines SL may transmit the scan signal from the gate driver GD to the pixel circuits of the plurality of sub pixels SP.

A plurality of auxiliary high potential power lines AVL1 extending in the row direction is disposed on the first substrate 110 of the display panel PN. The plurality of auxiliary high potential power lines AVL1 may be disposed in an area between the plurality of pixel areas UPA. The plurality of auxiliary high potential power lines AVL1 extending in the row direction may be electrically connected to the plurality of high potential power lines VL1 extending in the column direction through a contact hole and form a mesh structure. Therefore, the plurality of auxiliary high potential power lines AVL1 and the plurality of high potential power lines VL1 are configured to form a mesh structure to reduce or minimize voltage drop and voltage deviation.

A plurality of auxiliary low potential power lines AVL2 extending in the row direction is disposed on the first substrate 110 of the display panel PN. The plurality of auxiliary low potential power lines AVL2 may be disposed in an area between the plurality of pixel areas UPA. The plurality of auxiliary low potential power lines AVL2 extending in the row direction is electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and minimize voltage deviation.

The plurality of gate driving lines GVL extending in the row direction is disposed on the first substrate 110 of the display panel PN. The plurality of gate driving lines GVL may transmit various signals to the gate driver GD of the gate driving area GA. The plurality of gate driving lines GVL may include wiring lines which transmit a clock signal, a start signal, a gate high voltage, a gate low voltage, and the like to the gate driver GD. Therefore, various signals are transmitted from the gate driving line GVL to the gate driver GD to drive the gate driver GD.

A plurality of alignment keys AK1 and AK2 is disposed in an area between the plurality of pixel areas UPA in the display panel PN. The plurality of alignment keys AK1 and AK2 is used for alignment during the manufacturing process of the display panel PN. The plurality of alignment keys AK1 and AK2 includes a first alignment key AK1 and a second alignment key AK2.

The first alignment key AK1 may be disposed in the gate driving area GA between the plurality of pixel areas UPA. The first alignment key AK1 may be used to inspect an alignment position of the plurality of light emitting diodes 130. For example, the first alignment key AK1 may have a cross shape, but is not limited thereto.

The second alignment key AK2 may be disposed to overlap the high potential power line VL1 between the plurality of pixel areas UPA. In the high potential power line VL1, a hole overlapping the second alignment key AK2 is formed to divide the second alignment key AK2 and the high potential power line VL1. The second alignment key AK2 may be used to align the display panel PN and a donor. The display panel PN and the donor are aligned using the second alignment key AK2 and the plurality of light emitting diodes 130 of the donor may be transferred onto the display panel PN. For example, the second alignment key AK2 may have a circular ring shape, but is not limited thereto.

Referring to FIG. 4, the pixel circuit for driving the light emitting diode 130 is disposed in each of the plurality of sub pixels SP on the first substrate 110. The pixel circuit may include a plurality of thin film transistors and a plurality of capacitors. In FIGS. 4, for the convenience of description, only a driving transistor DT, a first capacitor C1, and a second capacitor C2, among configurations of the pixel circuit are illustrated. However, the pixel circuit may further include a switching transistor, a sensing transistor, an emission control transistor, and the like, but is not limited thereto.

First, a light shielding layer BSM is disposed on the first substrate 110. The light shielding layer BSM blocks light which is incident to an active layer ACT of the plurality of transistors to reduce or minimize a leakage current. For example, the light shielding layer BSM is disposed below the active layer ACT of the driving transistor DT to block light incident onto the active layer ACT. If light is irradiated onto the active layer ACT, leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the light shielding layer BSM. The buffer layer 111 may reduce permeation of moisture or impurities through the first substrate 110. The buffer layer 111 may be configured by a single layer or a double layer of silicon oxide SiOx or silicon nitride SiNx, but is not limited thereto. However, the buffer layer 111 may be omitted depending on a type of the first substrate 110 or a type of the thin film transistor, but is not limited thereto.

A driving transistor DT including an active layer ACT, a gate electrode GE, a source electrode SE, and a drain electrode DE is disposed on the buffer layer 111.

First, the active layer ACT of the driving transistor DT is disposed on the buffer layer 111. The active layer ACT may be formed of a semiconductor material such as an oxide semiconductor, amorphous silicon, or polysilicon, but is not limited thereto. Further, even though it is not illustrated in the drawings, other transistors, such as a switching transistor, a sensing transistor, and an emission control transistor, other than the driving transistor DT, may be further disposed. The active layers of the transistors may be also formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control transistor, may be formed of the same material, or formed of different materials.

The gate insulating layer 112 is disposed on the active layer ACT. The gate insulating layer 112 is an insulating layer which electrically insulates the active layer ACT from the gate electrode GE and may be configured by a single layer or a double layer of silicon oxide SiOx or silicon nitride SiNx, but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, contact holes through which each of the source electrode SE and the drain electrode DE is connected to the active layer ACT are formed. The first interlayer insulating layer 113 and the second interlayer insulating layer 114 are insulating layers which protect components therebelow and may be configured by single layers or double layers of silicon oxide SiOx or silicon nitride SiNx, but are not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode 130 and the drain electrode DE is connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

Next, the first capacitor electrode C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a may be integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the first substrate 110. The 2-1-th capacitor electrode C2a may be disposed on the same layer as the light shielding layer BSM and may be formed of the same material.

The 2-2-th capacitor electrode C2b is disposed on the buffer layer 111 and the gate insulating layer 112. The 2-2-th capacitor electrode C2b may be disposed on the same layer as the gate electrode GE and may be formed of the same material.

The 2-3-th capacitor electrode C2c is disposed on the first interlayer insulating layer 113. The 2-3-th capacitor electrode C2c may be configured by a first layer C2c1 and a second layer C2c2. The first layer C2c1 of the 2-3-th capacitor electrode C2c may be formed on the same layer as the 1-2-th capacitor electrode C1b with the same material. The first layer C2c1 may be disposed to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part extending from the source electrode SE of the driving transistor DT and may be connected to the first layer C2c1 through the contact hole of the second interlayer insulating layer 114.

Accordingly, the second capacitor C2 is electrically connected between the source electrode SE of the driving transistor DT and the light emitting diode 130 to increase capacitance inherent in the light emitting diode 130 and allow the light emitting diode 130 to emit light with a higher luminance.

A first passivation layer 115a is disposed on the driving transistor DT, the first capacitor C1, and the second capacitor C2. The first passivation layer 115a is an insulating layer which protects components below the first passivation layer 115a and may be configured by an inorganic material, such as silicon oxide SiOx or silicon nitride SiNx, but is not limited thereto.

A first planarization layer 116a is disposed on the first passivation layer 115a. The first planarization layer 116a may planarize an upper portion of the pixel circuit including the driving transistor DT. The first planarization layer 116a may be configured by a single layer or a double layer, and for example, configured by benzocyclobutene or an acrylic organic material, but is not limited thereto.

The reflection plate RF is disposed on the first planarization layer 116a. The reflection plate RF is a configuration which reflects light emitted from the plurality of light emitting diodes 130 above the first substrate 110 and may be formed with a shape corresponding to each of the plurality of sub pixels SP. One reflection plate RF may be disposed to cover the most area of one sub pixel SP. The reflection plate RF may reflect the light emitted from the light emitting diode 130 and may be also used as an electrode which electrically connects the light emitting diode 130 and the pixel circuit. Specifically, the reflection plate RF may be electrically connected to the source electrode SE of the driving transistor DT and the second capacitor C2 through a first contact hole CH1 of the first planarization layer 116a and the first passivation layer 115a. The reflection plate RF may be electrically connected to the first electrode 134 of the light emitting diode 130 through the second connection electrode CE2. Therefore, the reflection plate RF may electrically connect the driving transistor DT and the first electrode 134 of the light emitting diode 130. However, the reflection plate RF may electrically connect the second electrode 135 of the light emitting diode 130 and the high potential power line VL1, instead of connecting the first electrode 134 of the light emitting diode 130 and the driving transistor DT, but is not limited thereto.

The reflection plate RF may include various conductive layers in consideration of a light reflection efficiency and a resistance. For example, the reflection plate RF may use an opaque conductive layer such as silver (Ag), aluminum (Al), molybdenum (Mo), titanium (Ti), or an alloy thereof and a transparent conductive layer such as indium tin oxide together, but the structure of the reflection plate RF is not limited thereto.

The second passivation layer 115b is disposed on the reflection plate RF. The second passivation layer 115b is an insulating layer which protects components below the second passivation layer 115b and may be configured by a single layer or a double layer of silicon oxide SiOx or silicon nitride SiNx, but is not limited thereto.

An adhesive layer AD is disposed on the second passivation layer 115b. The adhesive layer AD is formed on the entire surface of the first substrate 110 to fix the light emitting diode 130 disposed on the adhesive layer AD. The adhesive layer AD may be formed of a photo curable adhesive material which is cured by light. For example, the adhesive layer AD may be formed of an acrylic material including a photoresist, but is not limited thereto. The adhesive layer AD may be formed on the entire surface of the first substrate 110 excluding pad areas PA1 and PA2 in which the first pad electrode PAD1 is disposed.

The plurality of light emitting diodes 130 is disposed in each of the plurality of sub pixels SP on the adhesive layer AD. The light emitting diode 130 is an element which emits light by a current and may include a red light emitting diode 130 which emits red light, a green light emitting diode 130 which emits green light, and a light emitting diode 130 which emits blue light and implement light with various colors including white by a combination thereof. For example, the light emitting diode 130 may be a light emitting diode (LED) or a micro LED, but is not limited thereto.

The plurality of light emitting diodes 130 includes a first semiconductor layer 131, an emission layer 132, a second semiconductor layer 133, a first electrode 134, and a second electrode 135.

The first semiconductor layer 131 is disposed on the adhesive layer AD and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium, tin (Sn), and the like, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN), gallium nitride (GaN), or the like, but is not limited thereto.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 134 may be a cathode. The first electrode 134 may be disposed on a top surface of the first semiconductor layer 131 which is exposed from the emission layer 132 and the second semiconductor layer 133. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 may be disposed on the top surface of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 135 may be an anode. The second electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 136 which encloses the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. In the encapsulation layer 136, a contact hole which exposes the first electrode 134 and the second electrode 135 is formed to electrically connect a first connection electrode CE1 and a second connection electrode CE2 to the first electrode 134 and the second electrode 135.

In the meantime, a part of the side surface of the first semiconductor layer 131 may be exposed from the encapsulation layer 136. The light emitting diode 130 manufactured on the wafer is separated from the wafer to be transferred onto the display panel PN. However, during the process of separating the light emitting diode 130 from the wafer, a part of the encapsulation layer 136 may be torn. For example, a part of the encapsulation layer 136 which is adjacent to a lower edge of the first semiconductor layer 131 of the light emitting diode 130 is torn during the process of separating the light emitting diode 130 from the wafer. Accordingly, a part of a lower side surface of the first semiconductor layer 131 may be exposed to the outside. However, even though the lower portion of the light emitting diode 130 is exposed from the encapsulation layer 136, the first connection electrode CE1 and the second connection electrode CE2 are formed after forming the second planarization layer 116b and the third planarization layer 116c which cover the side surface of the first semiconductor layer 131. Accordingly, a short problem may be reduced.

Next, the second planarization layer 116b and the third planarization layer 116c are disposed on the adhesive layer AD and the light emitting diode 130.

The second planarization layer 116b overlaps a part of side surfaces of the plurality of light emitting diodes 130 to fix and protect the plurality of light emitting diodes 130. The second planarization layer 116b may be formed using a halftone mask. Therefore, the second planarization layer 116b may be formed to have a step.

Specifically, a part of the second planarization layer 116b which is relatively adjacent to the light emitting diode 130 may be formed to have a smaller thickness and a part which is farther from the light emitting diode 130 may be formed to have a larger thickness. A part of the second planarization layer 116b which is adjacent to the light emitting diode 130 may be disposed to enclose the light emitting diode 130 and also may be in contact with a side surface of the light emitting diode 130. Therefore, the second planarization layer 116b may cover a torn part of the encapsulation layer 136 which protects a side surface of the first semiconductor layer 131 of the light emitting diode 130 during the process of separating the light emitting diode 130 from the wafer to be transferred onto the display panel PN. By doing this, contacts and short problems of the connection electrodes CE1 and CE2 and the first semiconductor layer 131 later may be suppressed.

The third planarization layer 116c is formed to cover upper portions of the second planarization layer 116b and the light emitting diode 130 and a contact hole which exposes the first electrode 134 and the second electrode 135 of the light emitting diode 130 may be formed. The first electrode 134 and the second electrode 135 of the light emitting diode 130 are exposed from the third planarization layer 116c. Third planarization layer 116c is partially disposed in an area between the first electrode 134 and the second electrode 135 to reduce a short problem. The second planarization layer 116b and the third planarization layer 116c may be configured by a single layer or a double layer, and for example, may be formed of a photoresist or an acrylic organic material, but is not limited thereto.

In the meantime, the third planarization layer 116c may cover only the light emitting diode 130 and an area adjacent to the light emitting diode 130. The third planarization layer 116c may be disposed in an area of the sub pixel SP enclosed by the bank BB and may be disposed in an island shape. A bank BB may be disposed in a part of the top surface of the second planarization layer 116b and the third planarization layer 116c may be disposed in the other part of the top surface of the second planarization layer 116b.

The first connection electrode CE1 and the second connection electrode CE2 are disposed on the third planarization layer 116c. The first connection electrode CE1 is an electrode which electrically connects the second electrode 135 of the light emitting diode 130 and the high potential power line VL1. The first connection electrode CE1 may be electrically connected to the second electrode 135 of the light emitting diode 130 through a contact hole formed in the third planarization layer 116c.

The second connection electrode CE2 is an electrode which electrically connects the first electrode 134 of the light emitting diode 130 and the driving transistor DT. The second connection electrode CE2 may be connected to the reflection plate RF of each of the plurality of sub pixels SP through contact holes formed in the third planarization layer 116c, the second planarization layer 116b, the adhesive layer AD, and the second passivation layer 115b. At this time, the reflection plate RF is also connected to the source electrode SE of the driving transistor DT so that the source electrode SE of the driving transistor DT and the first electrode 134 of the light emitting diode 130 may be electrically connected to each other.

The bank BB is disposed on the second planarization layer 116b exposed from the first connection electrode CE1 and the second connection electrode CE2, and the third planarization layer 116c. The bank BB may be disposed to be spaced apart from the light emitting diode 130 with a predetermined interval and overlap at least partially the reflection plate RF. For example, the bank BB may cover a part of the second connection electrode CE2 formed in the contact holes of the third planarization layer 116c and the second planarization layer 116b. Further, the bank BB may be disposed on the second planarization layer 116b with a predetermined interval from the light emitting diode 130. In this case, the bank BB and the third planarization layer 116c may be spaced apart from each other on a part of the second planarization layer 116b having a smaller thickness. That is, an end of the bank BB and an end of the third planarization layer 116c may be disposed on a part of the second planarization layer 116b having a smaller thickness formed by a halftone mask process to be spaced apart from each other.

The bank BB may be formed of an opaque material to reduce color mixture between the plurality of sub pixels SP and for example, may be formed of black resin (may also be referred to as a black bank BB), but is not limited thereto.

In the meantime, a thickness of a part of the bank BB which is formed in the contact holes of the third planarization layer 116c and the second planarization layer 116b to cover a part of the second connection electrode CE2 and a thickness of a part disposed on the second planarization layer 116b may be different from each other. Specifically, when the part of the bank BB covers a part of the second connection electrode CE2 formed in the contact holes of the third planarization layer 116c and the second planarization layer 116b, since the contact hole is formed from the second passivation layer 115b to the third planarization layer 116c, the bank BB may be disposed below the light emitting diode 130, that is, disposed to be lower than the light emitting diode 130. Therefore, the thickness of the part of the bank BB which covers a part of the second connection electrode CE2 formed in the contact holes of the third planarization layer 116c and the second planarization layer 116b may be larger than the thickness of a part of the bank BB disposed on the second planarization layer 116b.

A first protection layer 117 is disposed on the first connection electrode CE1, the second connection electrode CE2, and the bank BB. The first protection layer 117 is a layer for protecting components below the first protection layer 117, and may be configured by a single layer or a double layer of translucent epoxy, silicon oxide SiOx or silicon nitride SiNx, but is not limited thereto.

A plurality of first pad electrodes PAD1 is disposed in a first pad area PA1 and a second pad area PA2 of the first substrate 110. Each of the plurality of first pad electrodes PAD1 may be configured by a plurality of conductive layers. For example, each of the plurality of first pad electrodes PAD1 includes a first conductive layer PE1a, a second conductive layer PE1b, and a third conductive layer PE1c.

First, the first conductive layer PE1a is disposed on the second interlayer insulating layer 114. The first conductive layer PE1a may be formed of the same conductive material as the source electrode SE and the drain electrode DE and for example, may be configured by copper (Cu), aluminum (Al), molybdenum (Mo), nickel (Ni), titanium (Ti), chrome (Cr), or an alloy thereof, but is not limited thereto.

The first passivation layer 115a is disposed on the first conductive layer PE1a and the second conductive layer PE1b is disposed on the first passivation layer 115a. The second conductive layer PE1b may be formed of the same conductive material as the reflection plate RF and for example, may be configured by silver (Ag), aluminum (Al), molybdenum (Mo), or an alloy thereof, but is not limited thereto.

The third conductive layer PE1c is disposed on the second conductive layer PE1b. The third conductive layer PE1c may be formed of the same conductive material as the first connection electrode CE1 and the second connection electrode CE2, and for example, a transparent conductive material, such as indium tin oxide (ITO) or indium zinc oxide (IZO), but is not limited thereto.

At this time, even though it is not illustrated in the drawings, a part of the plurality of conductive layers of the first pad electrode PAD1 is electrically connected to a plurality of wiring lines on the first substrate 110 to supply various signals to a plurality of wiring lines and a plurality of sub pixels SP. For example, the first conductive layer PE1a and/or the second conductive layer PE1b of the first pad electrode PAD1 is connected to the data line DL, the high potential power line VL1, the low potential power line VL2, and the like disposed in the active area AA to transmit signals thereto.

A first metal layer ML1, a second metal layer ML2, and a plurality of insulating layers together may be disposed below the first pad electrode PAD1. The first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 may be sequentially disposed between the first pad electrode PAD1 and the first substrate 110. The first metal layer ML1 may be formed of the same conductive material as the gate electrode GE and the second metal layer ML2 may be formed of the same conductive material as a 1-2-th capacitor electrode C1b. However, the plurality of insulating layers, the first metal layer, and the second metal layer below the first pad electrode PAD1 may be omitted depending on a design and are not limited thereto.

A second substrate 120 is disposed below the first substrate 110. The second substrate 120 is a substrate which supports components disposed below the display device 100 and may be an insulating substrate. For example, the second substrate 120 may be formed of glass or resin. Further, the second substrate 120 may include polymer or plastic. The second substrate 120 may be formed of the same material as the first substrate 110. In some exemplary embodiments, the second substrate 120 may be formed of a plastic material having flexibility.

A bonding layer BDL is disposed between the first substrate 110 and the second substrate 120. The bonding layer BDL may be formed of a material which is cured by various curing methods to bond the first substrate 110 and the second substrate 120. The bonding layer BDL may be disposed only in a partial area between the first substrate 110 and the second substrate 120 or may be disposed in the entire area therebetween.

A plurality of second pad electrodes PAD2 is disposed on a rear surface of the second substrate 120. The plurality of second pad electrodes PAD2 is electrodes which transmit a signal from a driving component disposed on the rear surface of the second substrate 120 to a plurality of side lines SRL and a plurality of first pad electrodes PAD1 and a plurality of wiring lines on the first substrate 110. The plurality of second pad electrodes PAD2 is disposed in an end portion of the second substrate 120 in the non-active area NA to be electrically connected to the side line SRL which covers the end portion of the second substrate 120.

At this time, the plurality of second pad electrodes PAD2 may be also disposed so as to correspond to the plurality of pad areas PA1 and PA2. The plurality of first pad electrodes PAD1 may be disposed to correspond to the plurality of second pad electrodes PAD2, respectively, and then the first pad electrode PAD1 and the second pad electrode PAD2 which overlap each other may be electrically connected through the side line SRL.

Each of the plurality of second pad electrodes PAD2 includes a plurality of conductive layers. For example, each of the plurality of second pad electrodes PAD2 includes a fourth conductive layer PE2a, a fifth conductive layer PE2b, and a sixth conductive layer PE2c.

First, the fourth conductive layer PE2a is disposed below the second substrate 120. The fourth conductive layer PE2a may be configured by a conductive material such as copper (Cu), aluminum (Al), molybdenum (Mo), nickel (Ni), titanium (Ti), chrome (Cr), or an alloy thereof, but is not limited thereto.

The fifth conductive layer PE2b is disposed below the fourth conductive layer PE2a. The fifth conductive layer PE2b may be configured by a conductive material, such as copper (Cu), aluminum (Al), molybdenum (Mo), nickel (Ni), titanium (Ti), chrome (Cr), or an alloy thereof, but is not limited thereto.

The sixth conductive layer PE2c is disposed below the fifth conductive layer PE2b. The sixth conductive layer PE2c may be formed of a conductive material, for example, a transparent conductive material, such as indium tin oxide (ITO) or indium zinc oxide (IZO), but is not limited thereto.

The second protection layer 121 is disposed in the remaining area of the second substrate 120. The second protection layer 121 may protect various wiring lines and driving components formed on the second substrate 120. The second protection layer 121 may be configured by an organic insulating material, and for example, configured by benzocyclobutene or an acrylic organic insulating material, but is not limited thereto.

Even though it is not illustrated in the drawing, a driving component including a plurality of flexible films and a printed circuit board may be disposed on a rear surface of the second substrate 120. The plurality of flexible films is components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC may be disposed.

For example, the fourth conductive layer PE2a and/or the fifth conductive layer PE2b of the second pad electrode PAD2 extend to the plurality of flexible films disposed on the rear surface of the second substrate 120 to be electrically connected to the plurality of flexible films. The plurality of flexible films may supply various signals to the plurality of side lines SRL, the plurality of first pad electrodes PAD1, the plurality of wiring lines, and the plurality of sub pixels SP through the second pad electrode PAD2. Therefore, the signal from the driving component may be transmitted to the signal line and the plurality of sub pixels SP on the front surface of the first substrate 110 through the plurality of second pad electrodes PAD2 of the second substrate 120, the side line SRL, and the plurality of first pad electrodes PAD1 of the first substrate 110.

Next, the plurality of side lines SRL is disposed on the side surfaces of the first substrate 110 and the second substrate 120. The plurality of side lines SRL may electrically connect the plurality of first pad electrodes PAD1 formed on the top surface of the first substrate 110 and the plurality of second pad electrodes PAD2 formed on the rear surface of the second substrate 120. The plurality of side lines SRL may be disposed so as to enclose the side surface of the display device 100. Each of the plurality of side lines SRL may cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL may be formed by a pad printing method using a conductive ink, for example, including silver (Ag), copper (Cu), molybdenum (Mo), chrome (Cr), and the like.

A side insulating layer 140 which covers the plurality of side lines SRL is disposed. The side insulating layer 140 may be formed on the top surface of the first substrate 110, the side surface of the first substrate 110, the side surface of the second substrate 120, and the rear surface of the second substrate 120 to cover the side line SRL. The side insulating layer 140 may protect the plurality of side lines SRL.

In the meantime, when the plurality of side lines SRL is formed of a metal material, there may be a problem in that external light is reflected from the plurality of side lines SRL or light emitted from the light emitting diode 130 is reflected from the plurality of side lines SRL to be visibly recognized by the user. Therefore, the side insulating layer 140 is configured to include a black material to suppress reflection of the external light. For example, the side insulating layer 140 may be formed by a pad printing method using an insulating material including a black material, for example, a black ink.

A seal member 150 which covers the side insulating layer 140 is disposed. The seal member 150 is disposed so as to enclose the side surface of the display device 100 to protect the display device 100 from external impacts, moisture and oxygen, or the like. For example, the seal member 150 may be formed of polyimide (PI), poly urethane, epoxy, or acryl based insulating material, but is not limited thereto.

An optical film MF is disposed on the seal member 150, the side insulating layer 140, and the first protection layer 117. The optical film MF may be a functional film which implements a higher quality of images while protecting the display device 100. For example, the optical film MF may include an anti-scattering film, an anti-glare film, an anti-reflecting film, a low-reflecting film, an Oled transmittance controllable film, a polarizer, or the like, but is not limited thereto.

In the meantime, an edge of the seal member 150 and an edge of the optical film MF may be disposed on the same line. The optical film ML having a larger size is attached above the first substrate 110 during the manufacturing process of the display device 100 and the seal member 150 which covers the side insulating layer 140 may be formed. Thereafter, laser is irradiated on the seal member 150 and the optical film MF so as to correspond to an edge of the display device 100 to cut a part of the seal member 150 and the optical film MF. Accordingly, the size of the display device 100 may be adjusted by an outer periphery cutting process of the seal member 150 and the optical film MF and the edge of the display device 100 may be formed to be flat.

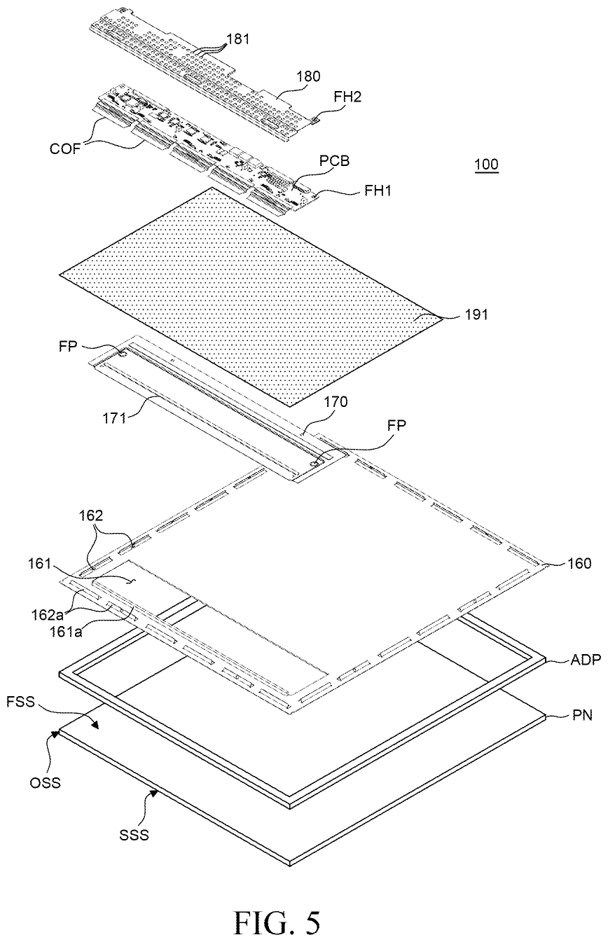

Hereinafter, a mechanical structure of the display device 100 according to the exemplary embodiment of the present disclosure will be described with reference to FIGS. 5 to 7.

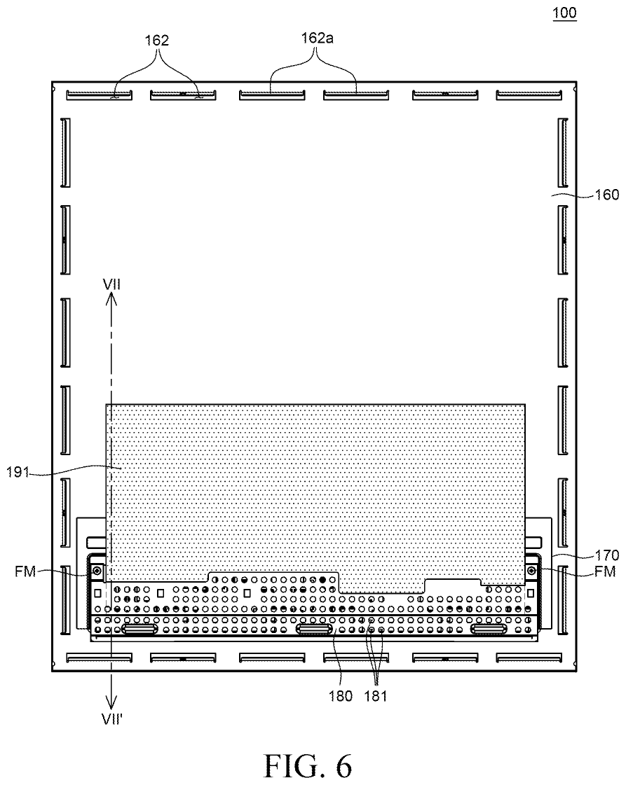

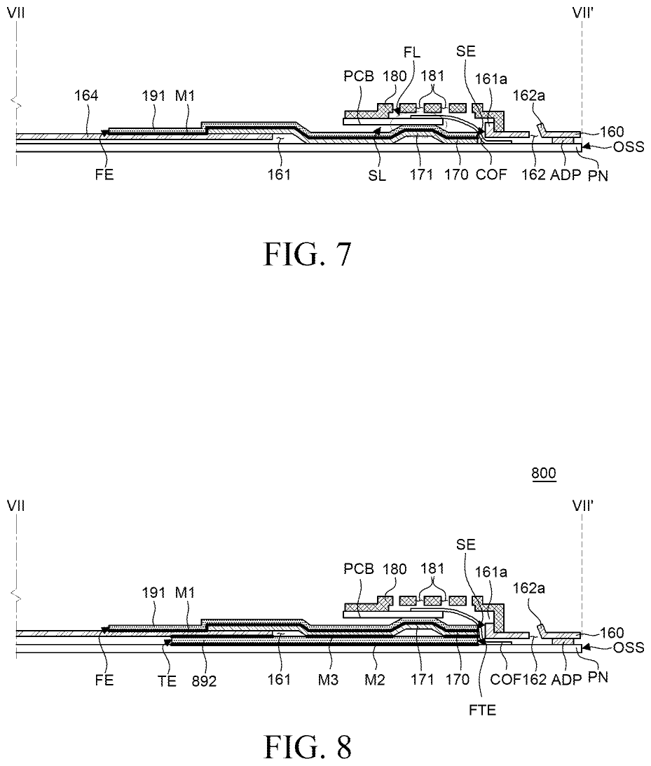

FIG. 5 is an exploded perspective view of a display device according to an exemplary embodiment of the present disclosure. FIG. 6 is a rear view of a display device according to an exemplary embodiment of the present disclosure. FIG. 7 is a cross-sectional view taken along the line VII-VII′ of FIG. 6.

Referring to FIG. 5, the display device 100 according to the exemplary embodiment of the present disclosure includes a display panel PN, a plurality of flexible films COF, a printed circuit board PCB, a cover bottom 160, a plate bottom 170, a cover shield 180, and an adhesive member ADP.

A plurality of flexible films COF is bonded onto a rear surface of the display panel PN. The plurality of flexible films COF may be electrically connected to the plurality of second pad electrodes PAD2 of the second substrate 120 of the display panel PN. The flexible film COF is a film in which various components are disposed on a base film having a ductility to supply a signal to the sub pixel SP and a driving component and may be electrically connected to the display panel PN.

A driving IC such as a gate driver IC or a data driver IC may be disposed on the plurality of flexible films COF. The driving IC is a component which processes data for displaying images and a driving signal for processing the data. The driving IC may be disposed in a chip on glass (COG), a chip on film (COF), or a tape carrier package (TCP) manner depending on a mounting method. However, for the convenience of description, it is described that the driving IC is mounted on the plurality of flexible films COF by a chip on film technique, but is not limited thereto.

The printed circuit board PCB is electrically connected to the plurality of flexible films COF. The printed circuit board PCB is a component which supplies signals to the driving IC. On the printed circuit board PCB, various components for supplying various signals to the driving IC may be disposed.

In the meantime, even though in FIG. 5, it is illustrated that five flexible films COF and one printed circuit board PCB are provided, the number of the plurality of flexible films COF and printed circuit boards PCB may vary depending on a design, but is not limited thereto.

The printed circuit board PCB includes a first fastening hole FH1. A fastening member FM is inserted into the first fastening hole FH1 formed in the printed circuit board PCB so that the printed circuit board PCB and the plate bottom 170 and the cover shield 180 may be fastened with each other.

The cover bottom 160 is disposed on a rear surface of the display panel PN. The cover bottom 160 may support and protect the display panel PN on the rear surface of the display panel PN. The cover bottom 160 is formed to have a shape corresponding to a planar shape of the display panel PN to cover the display panel PN. The cover bottom 160 may be formed of a material having a rigidity and a high thermal conductivity and for example, may be formed of a metal material such as aluminum (Al), copper (Cu), zinc (Zn), silver (Ag), gold (Au), iron (Fe), steel use stainless (SUS), or invar, or a plastic material.

The cover bottom 160 includes a first opening 161 and a plurality of second openings 162.

The first opening 161 of the cover bottom 160 is disposed so as to correspond to the plurality of flexible films COF and the printed circuit board PCB. The first opening 161 may be located on an area of the display panel to which the plurality of flexible films COF is bonded. For example, the plurality of flexible films COF is bonded to an area adjacent to one edge of the display panel PN and the first opening 161 may be also formed so as to correspond to an area adjacent to one edge of the display panel PN.

The plurality of flexible films COF and the printed circuit board PCB pass through the first opening 161 to be disposed on the rear surface of the cover bottom 160. Therefore, the plurality of flexible films COF and the printed circuit board PCB may be disposed on the cover bottom 160 without preparing a separate area for disposing the plurality of flexible films COF and the printed circuit board PCB between the cover bottom 160 and the display panel PN. At this time, the plate bottom 170 is seated in the first opening 161 of the cover bottom 160 to support the printed circuit board PCB, which will be described in more detail below.

A first protrusion 161a is disposed at an edge of the first opening 161. The first protrusion 161a may be disposed at one edge adjacent to one edge of the display panel PN, among edges of the first opening 161. The first protrusion 161a may be disposed at an edge most adjacent to a lower edge of the display panel PN, among edges of the first opening 161. The first protrusion 161a protrudes toward a direction perpendicular to the rear surface of the cover bottom 160 from one edge of the first opening 161. The first protrusion 161a is engaged with the cover shield 180, which will be described later, to restrict the movement of the cover shield 180 and guide a position of the cover shield 180.

Next, the plurality of second openings 162 of the cover bottom 160 is disposed along an edge of the cover bottom 160. The plurality of second openings 162 may be disposed to be parallel to the edge of the cover bottom 160. The plurality of second openings 162 is openings formed when the plurality of second protrusions 162a is formed.

The plurality of second protrusions 162a is parts which couple the display device 100 to a cabinet. The plurality of second protrusions 162a is used to fix the display device 100 to the cabinet in the form of a tile to form a tiling display device TD. The plurality of second protrusions 162a protrudes from one edges of the plurality of second openings 162 onto the rear surface of the cover bottom 160. The plurality of second protrusions 162a is formed by bending a part of the cover bottom 160 in a direction perpendicular to the rear surface of the cover bottom 160 and may have an L-shaped cross-sectional shape.

The second protrusion 162a may be formed by cutting and bending a part of the cover bottom 160. Therefore, when the plurality of second protrusions 162a is formed, the plurality of second openings 162 may be formed in a part in which the cover bottom 160 is cut. Therefore, the second protrusions 162a may be disposed on the edges of the plurality of second openings 162. For example, the second protrusion 162a may be disposed on an edge of the second opening 162 which is parallel to an edge of the cover bottom 160.

In the meantime, the display panel PN and the cover bottom 160 may be connected by means of the adhesive member ADP formed along the edge of the cover bottom 160.

Next, a first heat dissipation sheet 191 is disposed between the printed circuit board PCB and the display panel PN. The first heat dissipation sheet 191 is disposed between the printed circuit board PCB and the first opening 161 of the cover bottom 160.

The first heat dissipation sheet 191 may be formed of a material having a high thermal conductivity. For example, the first heat dissipation sheet 191 may be formed of one of graphite, aluminum (Al), and copper (Cu), but is not limited thereto.

The first heat dissipation sheet 191 extends to an outside of one end of the plate bottom 170 to overlap the rear surface of the cover bottom 160. For example, the first heat dissipation sheet 191 extends to an outside of one end of the plate bottom 170 which is disposed to be adjacent to a center portion CP of the display panel PN to overlap the rear surface of the cover bottom 160.

A first member M1 may be disposed to bond the first heat dissipation sheet 191 and the plate bottom 170. For example, the first member M1 may be a double-sided tape, but is not limited thereto.

The first member M1 is disposed in an area overlapping the first heat dissipation sheet 191 to bond the first heat dissipation sheet 191 and a configuration disposed below the first heat dissipation sheet 191. Therefore, when the first heat dissipation sheet 191 extends to the outside of one end of the plate bottom 170 to overlap the rear surface of the cover bottom 160, the first member M1 is also disposed to overlap the plate bottom 170 and the cover bottom 160 to bond the first heat dissipation sheet 191 and the plate bottom 170 and the cover bottom 160. Therefore, the first heat dissipation sheet 191 may be disposed to be adjacent to the display panel PN with the first member M1 and the plate bottom 170 and the first member M1 and the cover bottom 160 therebetween.

The plate bottom 170 is disposed between the printed circuit board PCB and the first opening 161 of the cover bottom 160. A part of the plate bottom 170 may cover the other edge of the first opening 161 and the cover bottom 160 and the other part of the plate bottom 170 may be disposed in the first opening 161. The plate bottom 170 passes through the first opening 161 to support the printed circuit board PCB disposed on the cover bottom 160. For example, as illustrated in FIG. 7, the plate bottom 170 may be disposed to be in contact with the display panel PN at the outside of the printed circuit board PCB and is spaced apart from the display panel PN in an area overlapping the printed circuit board PCB to support the printed circuit board PCB.

The plate bottom 170 extends to the outside of the first opening 161 to overlap the rear surface of the cover bottom 160. For example, the plate bottom 170 extends to the center portion CP of the display panel PN from the first opening 161 to overlap the rear surface of the cover bottom 160.

At this time, an area of the display panel PN to which one end of the plurality of flexible films COF is bonded may be a partial area of the first opening 161 which does not overlap the plate bottom 170. One ends of the plurality of flexible films COF overlap the first opening 161 and may be spaced apart from the plate bottom 170.

The plate bottom 170 may disperse and dissipate the heat generated from the printed circuit board PCB. The plate bottom 170 prevents the printed circuit board PCB form directly contacting the display panel PN to reduce or minimize the concentration of the heat of the printed circuit board PCB on a specific area of the display panel PN. Specifically, the printed circuit board PCB includes a plurality of components and among them, some driving chips which generate a lot of heat may be disposed. The plate bottom 170 disperse the heat generated from some driving chips of the printed circuit board PCB to the entire plate bottom 170 so as not to concentrate the heat on a partial area of the display panel PN adjacent to the driving chip and reduce the entire temperature deviation of the display panel PN.

The plate bottom 170 includes a bead 171. The bead 171 is a part protruding from one surface of the plate bottom 170 toward the printed circuit board PCB and may improve the rigidity of the plate bottom 170 while supporting the printed circuit board PCB. The bead 171 may be in direct contact with the printed circuit board PCB and heat generated from the printed circuit board PCB may disperse to the entire plate bottom 170 through the bead 171.

The plate bottom 170 includes a fastening unit FP. The fastening unit FP is a part to which the fastening member FM which passes through the first fastening hole FH1 of the printed circuit board PCB and the second fastening hole FH2 of the cover shield 180 is coupled. The fastening member FM is coupled to the fastening unit FP to fix the plate bottom 170, the printed circuit board PCB, and the cover shield 180 to each other. For example, the fastening unit FP may be a Pem-nut having a groove with a thread of a screw therein, but is not limited thereto.

Next, a cover shield 180 is disposed on the cover bottom 160, the plate bottom 170, and the printed circuit board PCB. The cover shield 180 may protect the printed circuit board PCB from the external impact. The cover shield 180 is formed of a material having a rigidity to protect the printed circuit board PCB, but is not limited thereto.

The cover shield 180 may be disposed on the rear surface of the cover bottom 160 to cover the printed circuit board PCB. One edge of the cover shield 180 is bent toward the cover bottom 160 to be in contact with the outer surface of the first protrusion 161a. For example, one edge of the cover shield 180 is bent in an L-shape and may be in contact with an outer side surface of the first protrusion 161a of the cover bottom 160. Therefore, the first protrusion 161a and one side portion of the cover shield 180 are engaged with each other to restrict the movement of the cover shield 180 and guide the position of the cover shield 180.

The cover shield 180 includes a plurality of heat dissipation holes 181. The plurality of heat dissipation holes 181 may be disposed in the most area of the cover shield 180. The plurality of heat dissipation holes 181 is formed to dissipate the heat generated from the printed circuit board PCB to the outside of the cover shield 180. Some driving chips which generate a lot of heat, among the plurality of components of the printed circuit board PCB, may be exposed from the cover shield 180. Some driving chips which generate a lot of heat are exposed from the cover shield 180 to efficiently dissipate heat generated from the driving chips. Therefore, additional grooves or holes may be formed in a part of the cover shield 180 according to a position of the driving chip which generates a lot of heat.

The cover shield 180 includes a plurality of second fastening holes FH2. A fastening member FM is inserted into the second fastening hole FH2 to fix the cover shield 180 to the printed circuit board PCB and the plate bottom 170. Specifically, the cover shield 180 and the printed circuit board PCB may be fixed to the plate bottom 170 by coupling the fastening member FM which passes through both the second fastening hole FH2 of the cover shield 180 and the first fastening hole FH1 of the printed circuit board PCB to the fastening unit FP of the plate bottom 170. For example, the fastening member FM may be a bolt which is screwed to the fastening unit FP which is a nut, but is not limited thereto.

Next, an adhesive member ADP is disposed between the cover bottom 160 and the display panel PN. The adhesive member ADP may be formed of a material with adhesiveness to fix the cover bottom 160 onto the rear surface of the display panel PN. The adhesive member ADP may be disposed along an edge of the display panel PN and an edge of the cover bottom 160. The adhesive member ADP may be formed in a frame shape corresponding to an edge of the display panel PN. For example, the adhesive member ADP may be a foam tape having adhesiveness, but is not limited thereto.

The adhesive member ADP may be disposed to be adjacent to the edge of the cover bottom 160.

As shown in FIG. 7, the display panel PN has a first surface FSS, a second surface SSS opposite the first surface FSS. The display panel PN also has an outermost side surface OSS between the first surface FSS and the second surface SSS (see FIGS. 5, and 7-10). In one embodiment, the first heat dissipation sheet 191 contacts the printed circuit board PCB at a first location FL. During operation, the printed circuit board PCB may generate heat and it is beneficial to dissipate the heat generated from the printed circuit board PCB. Accordingly, the first heat dissipation sheet 191 is arranged such that it contacts the printed circuit board PCB at the first location FL. To further dissipate heat generated from the printed circuit board PCB, the plurality of heat dissipation holes 181 is also formed adjacent to the first location FL. As noted previously, the plurality of heat dissipation holes 181 helps dissipate the heat generated from the printed circuit board PCB to the outside of the cover shield 180. In one embodiment, the first heat dissipation sheet 191 is spaced apart from the printed circuit board PCB at a second location SL adjacent to the first location FL. That is, the first heat dissipation sheet 191 may have a bent shape that protrudes upward (in a direction opposite of the display panel PN) and the protruded upward portion of the first heat dissipation sheet 191 contacts the printed circuit board PCB.

The cover shield 180 includes a plurality of heat dissipation holes 181. The plurality of heat dissipation holes 181 may be disposed in the most area of the cover shield 180. The plurality of heat dissipation holes 181 is formed to dissipate the heat generated from the printed circuit board PCB to the outside of the cover shield 180. Some driving chips which generate a lot of heat, among the plurality of components of the printed circuit board PCB, may be exposed from the cover shield 180. Some driving chips which generate a lot of heat are exposed from the cover shield 180 to efficiently dissipate heat generated from the driving chips. Therefore, additional grooves or holes may be formed in a part of the cover shield 180 according to a position of the driving chip which generates a lot of heat.

As shown in FIG. 7, the first member M1 is disposed below the first heat dissipation sheet 191. In one embodiment, the first member M1 has the same length as the first heat dissipation sheet 191. The first heat dissipation sheet 191 has a first end FE and a second end SE that is opposite the first end FE. The second end SE is closer to the outermost side surface OSS of the display panel PN than the first end FE. The first end FE, on the other hand, is closer to the center portion CP of the display panel than the second end SE. The first member M1 may also extend from the first end FE to the second end SE such that it has substantially the same length as the first heat dissipation sheet 191. Further, since the first member M1 has substantially the same length as the first heat dissipation sheet 191, the first member M1 may fully overlap with the first heat dissipation sheet 191 from a plan view.

Various chips for driving the display device are disposed on the printed circuit board of the display device. For example, on the printed circuit board, an element used to generate various voltages, such as a high potential power, a low potential power, and a reference power, that is, an IC chip may be disposed. In the meantime, when the display device is driven, chips disposed on the printed circuit board may generate heat. Specifically, a chip, such as an IC FET or a buck IC which generates a high potential voltage, like a power management integrated circuit (PMIC), may generate the highest heat, among various chips disposed on the printed circuit board. Therefore, heat is concentrated in an area in which the printed circuit board is disposed, for example, in a lower area of the display panel so that entire temperature deviation of the display panel may be increased. When there is a temperature deviation in each area of the display panel, spots may be seen from the display panel, a color difference may occur, or a display quality may be degraded.

Accordingly, in the display device 100 according to the exemplary embodiment of the present disclosure, the first heat dissipation sheet 191 is disposed in a specific area of the display panel PN in which high heat is generated, for example, an area overlapping the printed circuit board PCB. In one embodiment, the first heat dissipation sheet 191 fully overlaps the printed circuit board PCB from a plan view. Therefore, it is possible to reduce the entire temperature deviation of the display panel PN. The first heat dissipation sheet 191 is disposed between the display panel PN and the printed circuit board PCB so that the entire temperature of the display panel PN is uniform. For example, the first heat dissipation sheet 191 is disposed to be in contact with the surface of the printed circuit board PCB and the surface of the display panel PN to uniformly disperse heat generated from the printed circuit board PCB disposed in a lower area of the display panel to an intermediate area and an upper area of the display panel PN. Therefore, the heat generated from the printed circuit board PCB is dispersed to the entire surface of the display panel PN to implement uniformly the entire temperature of the display panel PN to reduce or minimize the spots or color differences and improve a display quality.

FIG. 8 is a cross-sectional view of a display device according to another exemplary embodiment of the present disclosure. The only difference between a display device 800 of FIG. 8 and the display device 100 of FIGS. 1 to 7 is that a second heat dissipation sheet is added, but the other configuration is substantially the same, so that a redundant description will be omitted.

The first heat dissipation sheet 191 is disposed between the printed circuit board PCB and the first opening 161 of the cover bottom 160.

Referring to FIG. 8, a second heat dissipation sheet 892 is disposed between the display panel PN and the cover bottom 160. The second heat dissipation sheet 892 may be disposed to overlap a part of the first heat dissipation sheet 191 with the cover bottom 160 and the plate bottom 170 therebetween.

The second heat dissipation sheet 892 may be formed of the same material as the first heat dissipation sheet 191. For example, the second heat dissipation sheet 892 may be formed of one of graphite, aluminum (Al), and copper (Cu), but is not limited thereto.

The second heat dissipation sheet 892 may extend between one end of the plate bottom 170 and a center portion CP of the display panel PN. At this time, one end of the second heat dissipation sheet 892 may be disposed inside from one end of the first heat dissipation sheet 191. For example, one end of the second heat dissipation sheet 892 disposed to be adjacent to the center portion CP of the display panel PN may be disposed inside from one end of the first heat dissipation sheet 191 disposed to be adjacent to the center portion CP of the display panel PN. At this time, one end of the second heat dissipation sheet 892 extends to the outside of the first opening 161 of the cover bottom 160 to overlap a forming unit 164 of the cover bottom 160. The second heat dissipation sheet 892 may have a flat top surface along the rear surface of the display panel PN.

Referring to FIG. 8, a second member M2 and a third member M3 which are bonded to the second heat dissipation sheet 892 may be disposed.

The second member M2 is disposed between the second heat dissipation sheet 892 and the display panel PN to bond the second heat dissipation sheet 892 and the display panel PN.

Therefore, the second member M2 may be disposed with a flat top surface along the rear surface of the display panel PN.

The third member M3 is disposed between the second heat dissipation sheet 892 and the cover bottom 160 and the plate bottom 170 to bond the second heat dissipation sheet 892 and the cover bottom 160 and the plate bottom 170. At this time, the third member M3 may be disposed only in an area which is in contact with the cover bottom 160 and the plate bottom 170. For example, the third member M3 may be disposed to be spaced apart from the rear surface of the display panel PN with an area overlapping the bead 171 therebetween. That is, the third member M3 is disposed between the second heat dissipation sheet 892 and the plate bottom 170 in an area overlapping the first opening 161 to bond the second heat dissipation sheet 892 and the plate bottom 170. Further, the third member M3 is disposed between the second heat dissipation sheet 892 and the cover bottom 160 at the outside of the first opening 161 to bond the second heat dissipation sheet 892 and the cover bottom 160.

Therefore, one surface of the second heat dissipation sheet 892 may be disposed to be adjacent to the display panel PN and the other surface of the second heat dissipation sheet 892 may be disposed to be adjacent to the printed circuit board PCB with the first heat dissipation sheet 191 therebetween.

Accordingly, in the display device 800 according to another exemplary embodiment of the present disclosure, the first heat dissipation sheet 191 is disposed in an area overlapping the printed circuit board PCB to dissipate heat generated from the printed circuit board PCB to the entire surface of the display panel PN. Therefore, the entire temperature of the display panel PN is uniformly implemented to reduce or minimize spots or color differences and improve the display quality.

Further, in the display device 800 according to another exemplary embodiment of the present disclosure, the second heat dissipation sheet 892 which is disposed along the rear surface of the display panel PN is disposed between the first heat dissipation sheet 191 and the display panel PN in an area overlapping the printed circuit board PCB. Therefore, the heat generated from the printed circuit board PCB may be transmitted to the second heat dissipation sheet 892 through the first heat dissipation sheet 191 and the second heat dissipation sheet 892 is disposed to be in close contact with the rear surface of the display panel PN. Accordingly, the heat transmitted to the second heat dissipation sheet 892 may be diffused to the entire surface of the display panel PN with the third member M3 therebetween. Therefore, in the display device 800 according to another exemplary embodiment of the present disclosure, the entire temperature of the display panel PN is uniformly implemented to reduce or minimize spots or color differences and improve the display quality.

Further, in the display device 800 according to another exemplary embodiment of the present disclosure, an area of overlapping the first heat dissipation sheet 191 which is more adjacent to the printed circuit board PCB and the display panel PN is larger than an area of overlapping the second heat dissipation sheet 892 and the display panel PN. Therefore, a heat transfer efficiency to transmit the heat generated from the printed circuit board PCB to the display panel PN may be improved to improve the heat dissipation efficiency.

Referring to FIG. 8, the first heat dissipation sheet 191 has a first end FE and a second end SE that is opposite the first end FE. The second end SE is closer to the outermost side surface OSS of the display panel PN than the first end FE. The first end FE, on the other hand, is closer to the center portion CP of the display panel than the second end SE. Similarly, the second heat dissipation sheet 892 has a third end TE and a fourth end FTE that is opposite the third end TE. The fourth end FTE is closer to the outermost side surface OSS of the display panel PN than the third end TE. The third end TE, on the other hand, is closer to the center portion CP of the display panel than the fourth end FTE. Here, the second member M2 may also extend from the third end TE to the fourth end FTE such that it has substantially the same length as the second heat dissipation sheet 892. Further, since the second member M2 has substantially the same length as the second heat dissipation sheet 892, the second member M2 may fully overlap with the second heat dissipation sheet 892 from a plan view. The third member M3, on the other hand, is discontinuous at some portions and is spaced apart from each other at openings (e.g., the first opening 161).

However, as shown in FIG. 8, the first heat dissipation sheet 191 extends further towards a direction opposite the outermost side surface OSS of the display panel PN (i.e., a direction toward the center portion CP of the display panel PN) than the second heat dissipation sheet 892. In other words, the first end FE of the first heat dissipation sheet 191 extends further towards the direction of the center portion CP of the display panel PN than the third end TE of the second heat dissipation sheet 892. Accordingly, since the first heat dissipation sheet 191 is greater in length than the second heat dissipation sheet 892, the first heat dissipation sheet 191 fully overlaps the second heat dissipation sheet 892 when seen from a plan view.

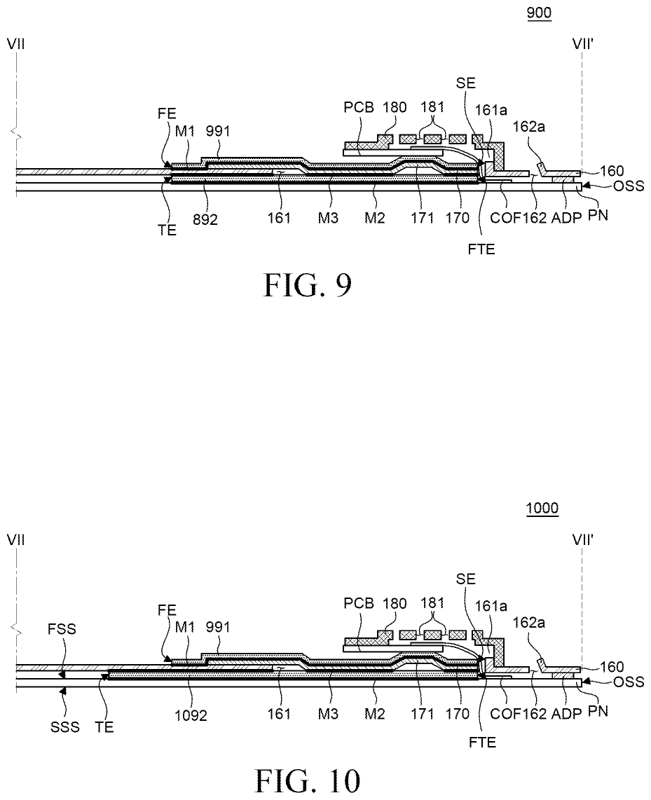

FIG. 9 is a cross-sectional view of a display device according to still another exemplary embodiment of the present disclosure. The only difference between a display device 900 of FIG. 9 and the display device 800 of FIG. 8 is a first heat dissipation sheet 991, but other configuration is substantially the same, so that a redundant description will be omitted.

The first heat dissipation sheet 991 and the second heat dissipation sheet 892 are disposed between the printed circuit board PCB and the display panel PN.

The second heat dissipation sheet 892 may be disposed in an area overlapping an entire top surface of the first heat dissipation sheet 991. Therefore, one end of the second heat dissipation sheet 892 may be disposed to overlap one end of the first heat dissipation sheet 991.

For example, when one end of the second heat dissipation sheet 892 disposed to be adjacent to the center portion CP of the display panel PN is disposed to be adjacent to the plate bottom 170, one end of the first heat dissipation sheet 991 may be also disposed to be adjacent to the plate bottom 170. In contrast, when one end of the second heat dissipation sheet 892 disposed to be adjacent to the center portion CP of the display panel PN extends to the center portion CP of the display panel PN, one end of the first heat dissipation sheet 991 may also extend to the center portion CP of the display panel PN.

Referring to FIG. 9, the first heat dissipation sheet 991 has a first end FE and a second end SE that is opposite the first end FE. The second end SE is closer to the outermost side surface OSS of the display panel PN than the first end FE. The first end FE, on the other hand, is closer to the center portion CP of the display panel than the second end SE. Similarly, the second heat dissipation sheet 892 has a third end TE and a fourth end FTE that is opposite the third end TE. The fourth end FTE is closer to the outermost side surface OSS of the display panel PN than the third end TE. The third end TE, on the other hand, is closer to the center portion CP of the display panel than the fourth end FTE. Here, the second member M2 may also extend from the third end TE to the fourth end FTE such that it has substantially the same length as the second heat dissipation sheet 892. Further, since the second member M2 has substantially the same length as the second heat dissipation sheet 892, the second member M2 may fully overlap with the second heat dissipation sheet 892 from a plan view.

In FIG. 9, the first heat dissipation sheet 991 and the second heat dissipation sheet 892 both extends towards a direction opposite the outermost side surface OSS of the display panel PN (i.e., a direction toward the center portion CP of the display panel PN). Here, the first end FE of the first heat dissipation sheet 991 and the third end TE of the second heat dissipation sheet 892 extends towards the direction of the center portion CP of the display panel PN to the same extent. That is, the first end FE of the first heat dissipation sheet 991 and the third end TE of the second heat dissipation sheet 892 may coincide with each other from a plan view.

Accordingly, in the display device 900 according to still another exemplary embodiment of the present disclosure, the first heat dissipation sheet 991 is disposed in an area overlapping the printed circuit board PCB to dissipate heat generated from the printed circuit board PCB to the entire surface of the display panel PN. Therefore, the entire temperature of the display panel PN is uniformly implemented to reduce or minimize spots or color differences and improve the display quality.

Further, in the display device 900 according to still another exemplary embodiment of the present disclosure, the second heat dissipation sheet 892 which is disposed along the rear surface of the display panel PN is disposed between the first heat dissipation sheet 991 and the display panel PN in an area overlapping the printed circuit board PCB. Therefore, the entire temperature of the display panel PN is uniformly implemented to reduce or minimize spots or color differences and improve the display quality.

Further, in the display device 900 according to still another exemplary embodiment of the present disclosure, the first heat dissipation sheet 991 and the second heat dissipation sheet 892 are disposed with the same area to reduce the manufacturing cost and a temperature deviation of the display device 900. When the second heat dissipation sheet 892 is disposed to overlap more than half of the display panel PN, the heat generated from the center portion CP of the display panel PN may be transmitted to the printed circuit board PCB. Therefore, the heat generated from the printed circuit board PCB is not dispersed to increase the temperature deviation of the display panel PN. Further, when the first heat dissipation sheet 991 is disposed to overlap more than half of the display panel PN, there may be a problem in that the manufacturing cost of the first heat dissipation sheet 991 is relatively increased to increase the manufacturing cost of the display device 900. Therefore, in the display device 900 according to still another exemplary embodiment of the present disclosure, the first heat dissipation sheet 991 and the second heat dissipation sheet 892 are disposed with the same area to reduce the manufacturing cost and a temperature deviation of the display device 900.

FIG. 10 is a cross-sectional view of a display device according to still another exemplary embodiment of the present disclosure. The only difference between a display device 1000 of FIG. 10 and the display device 900 of FIG. 9 is a second heat dissipation sheet 1092, but other configuration is substantially the same, so that a redundant description will be omitted.

The first heat dissipation sheet 991 and a second heat dissipation sheet 1092 are disposed between the printed circuit board PCB and the display panel PN.

Referring to FIG. 10, the first heat dissipation sheet 991 may be disposed to overlap a part of the second heat dissipation sheet 1092 with the cover bottom 160 and the plate bottom 170 therebetween.

One end of the second heat dissipation sheet 1092 may be disposed outside from one end of the first heat dissipation sheet 991. For example, one end of the second heat dissipation sheet 1092 disposed to be adjacent to the center portion CP of the display panel PN may be disposed outside from one end of the first heat dissipation sheet 991 disposed to be adjacent to the center portion CP of the display panel PN. Therefore, an area of overlapping the second heat dissipation sheet 1092 and the display panel PN may be larger than an area of overlapping the first heat dissipation sheet 991 and the display panel PN.

Referring to FIG. 10, the first heat dissipation sheet 991 has a first end FE and a second end SE that is opposite the first end FE. The second end SE is closer to the outermost side surface OSS of the display panel PN than the first end FE. The first end FE, on the other hand, is closer to the center portion CP of the display panel than the second end SE. Similarly, the second heat dissipation sheet 1092 has a third end TE and a fourth end FTE that is opposite the third end TE. The fourth end FTE is closer to the outermost side surface OSS of the display panel PN than the third end TE. The third end TE, on the other hand, is closer to the center portion CP of the display panel than the fourth end FTE. Here, the second member M2 may also extend from the third end TE to the fourth end FTE such that it has substantially the same length as the second heat dissipation sheet 1092. Further, since the second member M2 has substantially the same length as the second heat dissipation sheet 1092, the second member M2 may fully overlap with the second heat dissipation sheet 1092 from a plan view.

In FIG. 10, the second heat dissipation sheet 1092 extends further towards a direction opposite the outermost side surface OSS of the display panel PN (i.e., a direction toward the center portion CP of the display panel PN) than the first heat dissipation sheet 991. In other words, the third end TE of the second heat dissipation sheet 1092 extends further towards the direction of the center portion CP of the display panel PN than the first end FE of the first heat dissipation sheet 991. Accordingly, since the second heat dissipation sheet 1092 is greater in length than the first heat dissipation sheet 991, the second heat dissipation sheet 1092 fully overlaps the first heat dissipation sheet 991 when seen from a plan view.

Accordingly, in the display device 1000 according to still another exemplary embodiment of the present disclosure, the first heat dissipation sheet 991 is disposed in an area overlapping the printed circuit board PCB to dissipate heat generated from the printed circuit board PCB to the entire surface of the display panel PN. Therefore, the entire temperature of the display panel PN is uniformly implemented to reduce or minimize spots or color differences and improve the display quality.

Further, in the display device 1000 according to still another exemplary embodiment of the present disclosure, the second heat dissipation sheet 1092 which is disposed along the rear surface of the display panel PN is disposed between the first heat dissipation sheet 991 and the display panel PN in an area overlapping the printed circuit board PCB. Therefore, the entire temperature of the display panel PN is uniformly implemented to reduce or minimize spots or color differences and improve the display quality.

Further, in the display device 1000 according to still another exemplary embodiment of the present disclosure, the second heat dissipation sheet 1092 which is disposed along the rear surface of the display panel PN is disposed to have a larger area than the first heat dissipation sheet 991. Accordingly, heat generated from the printed circuit board PCB may be uniformly dispersed to the surface of the display panel PN. Further, the first heat dissipation sheet 991 is disposed with a smaller area to reduce the manufacturing cost of the first heat dissipation sheet 991.

The exemplary embodiments of the present disclosure can also be described as follows:

According to an aspect of the present disclosure, there is provided a display device. The display device comprises a display panel, a cover bottom which is disposed on a rear surface of the display panel and includes a first opening. The display device further comprises a plate bottom which is disposed to overlap the first opening on the rear surface of the display panel. The display device further comprises a printed circuit board which is disposed on a rear surface of the plate bottom and is connected to the display panel. The display device further comprises a heat dissipation sheet disposed between the display panel and the printed circuit board.

The heat dissipation sheet may include a first heat dissipation sheet disposed between the plate bottom and the printed circuit board.

The plate bottom may be disposed to be spaced apart from the display panel in an area overlapping the printed circuit board and be disposed to be in contact with the display panel at an outside of the printed circuit board. The first heat dissipation sheet may be disposed to be in contact with the printed circuit board.

The display device may further comprise a first member which bonds the first heat dissipation sheet and the plate bottom.

The plate bottom may extend to an outside of the first opening to overlap a rear surface of the cover bottom. The first heat dissipation sheet may extend to an outside of one end of the plate bottom to overlap the rear surface of the cover bottom.

The display device may further comprise a first member which bonds the first heat dissipation sheet and the plate bottom and the cover bottom.

The heat dissipation sheet may include a second heat dissipation sheet disposed between the display panel and the cover bottom.

The second heat dissipation sheet may have a flat top surface along the rear surface of the display panel.

The second heat dissipation sheet may extend between one end of the plate bottom and a center portion of the display panel.

The display device may further comprise a second member which bonds the second heat dissipation sheet and the display panel.

The display device may further comprise a third member which bonds the second heat dissipation sheet and the cover bottom and the plate bottom, wherein the third member is disposed only in an area which is in contact with the cover bottom and the plate bottom.

One end of the second heat dissipation sheet may be disposed inside from one end of the first heat dissipation sheet.

One end of the second heat dissipation sheet may overlap one end of the first heat dissipation sheet.

One end of the second heat dissipation sheet may be disposed outside from one end of the first heat dissipation sheet.

The heat dissipation sheet may be formed of one of graphite, aluminum (Al), and copper (Cu).

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel;
a cover bottom which is disposed on a rear surface of the display panel and includes a first opening;
a plate bottom which is disposed to overlap the first opening on the rear surface of the display panel;
a printed circuit board which is disposed on a rear surface of the plate bottom and is electrically connected to the display panel; and
a heat dissipation sheet disposed between the display panel and the printed circuit board.

2. The display device according to claim 1, wherein the heat dissipation sheet includes a first heat dissipation sheet disposed between the plate bottom and the printed circuit board.

3. The display device according to claim 2, wherein the plate bottom is disposed to be spaced apart from the display panel in an area overlapping the printed circuit board and is disposed to be in contact with the display panel at an outside of the printed circuit board and the first heat dissipation sheet is disposed to be in contact with the printed circuit board.

4. The display device according to claim 3, further comprising:
a first member positioned between the first heat dissipation sheet and the plate bottom and bonds the first heat dissipation sheet and the plate bottom.

5. The display device according to claim 2, wherein the plate bottom extends to an outside of the first opening to overlap a rear surface of the cover bottom and the first heat dissipation sheet extends to an outside of one end of the plate bottom to overlap the rear surface of the cover bottom.

6. The display device according to claim 5, further comprising:
a first member which bonds the first heat dissipation sheet and the plate bottom and the cover bottom.

7. The display device according to claim 2, wherein the heat dissipation sheet includes a second heat dissipation sheet disposed between the display panel and the cover bottom.

8. The display device according to claim 7, wherein the second heat dissipation sheet has a flat top surface along the rear surface of the display panel.

9. The display device according to claim 8, wherein the second heat dissipation sheet extends between one end of the plate bottom and a center portion of the display panel.

10. The display device according to claim 7, further comprising:
a second member which bonds the second heat dissipation sheet and the display panel.

11. The display device according to claim 7, further comprising:
a third member which bonds the second heat dissipation sheet and the cover bottom and the plate bottom,
wherein the third member is disposed only in an area which is in contact with the cover bottom and the plate bottom.

12. The display device according to claim 7, wherein one end of the second heat dissipation sheet is disposed inside from one end of the first heat dissipation sheet.

13. The display device according to claim 7, wherein one end of the second heat dissipation sheet overlaps one end of the first heat dissipation sheet.

14. The display device according to claim 7, wherein one end of the second heat dissipation sheet is disposed outside from one end of the first heat dissipation sheet.

15. The display device according to claim 1, wherein the heat dissipation sheet includes any one of graphite, aluminum, and copper.

16. A display device, comprising:
a display panel having a first surface, a second surface opposite the first surface, and an outermost side surface between the first surface and the second surface;
a plate bottom on the first surface of the display panel;
a circuit board on the plate bottom, the circuit board being electrically connected to the display panel; and
at least one heat dissipation sheet disposed between the display panel and the printed circuit board.

17. The display device of claim 16, wherein the at least one heat dissipation sheet includes a first heat dissipation sheet,
wherein the first heat dissipation sheet contacts the circuit board at a first location.

18. The display device of claim 17, wherein the first heat dissipation sheet is spaced apart from the circuit board at a second location adjacent to the first location.

19. The display device of claim 17, comprising:
a first member between the first heat dissipation sheet and the plate bottom,
wherein the first member fully overlaps with the first dissipation sheet from a plan view.

20. The display device of claim 16, wherein the at least one heat dissipation sheet includes a first heat dissipation sheet and a second heat dissipation sheet,
wherein the first heat dissipation sheet is between the second heat dissipation sheet and the circuit board,
wherein the second heat dissipation sheet is between the display panel and the first dissipation sheet.

21. The display device of claim 20, wherein the first heat dissipation sheet extends further towards a direction opposite the outermost side surface of the display panel than the second heat dissipation sheet, and
wherein the first heat dissipation sheet fully overlaps the second heat dissipation sheet from a plan view.

22. The display device of claim 21, comprising:
a first member between the first heat dissipation sheet and the plate bottom;
a second member between the second heat dissipation sheet and the display panel; and
a third member between the second heat dissipation sheet and the plate bottom.

23. The display device of claim 20, wherein the first heat dissipation sheet includes a first end and a second end opposite the first end, the second end being closer to the outermost side surface of the display panel than the first end,
wherein the second heat dissipation sheet includes a third end and a fourth end opposite the third end, the fourth end being closer to the outermost side surface of the display panel than the third end, and
wherein the first end of the first heat dissipation sheet and the third end of the second heat dissipation sheet coincide with each other from a plan view.

24. The display device of claim 20, wherein the first heat dissipation sheet includes a first end and a second end opposite the first end, the second end being closer to the outermost side surface of the display panel than the first end,
wherein the second heat dissipation sheet includes a third end and a fourth end opposite the third end, the fourth end being closer to the outermost side surface of the display panel than the third end, and
wherein the third end of the second heat dissipation sheet extends further toward a direction opposite the outermost side surface of the display panel than the first end of the first heat dissipation sheet.
